(19) United States
(12) Patent Application Publication
(10) Pub. No.: US 2015/0244391 A1
(43) Pub. Date: Aug. 27, 2015

(54) RAMP SIGNAL GENERATOR USING PROGRAMMABLE GAIN AMPLIFIER

(71) Applicant: SK hynix Inc., Gyeonggi-do (KR)

(72) Inventor: Si-Wook YOO, Gyeonggi-do (KR)

(21) Appl. No.: 14/444,698

(22) Filed: Jul. 28, 2014

(30) Foreign Application Priority Data
Feb. 27, 2014 (KR) 10-2014-0023196

(51) Int. Cl. H03M 1/70; H03K 4/06

(52) U.S. Cl. CPC H03M 1/70; H03K 4/06

(57) ABSTRACT

According to an embodiment of the inventive concept disclosed in this application, a ramp signal generator may include a ramp signal generation unit suitable for generating a ramp signal, a gain amplification control unit suitable for outputting a gain amplification control signal for controlling a voltage gain in response to a control signal from a control unit; and a programmable gain amplifier (PGA) suitable for controlling the voltage gain by amplifying the ramp signal provided from the ramp signal generation unit in response to the gain amplification control signal from the gain amplification control unit.

### CROSS-REFERENCE TO RELATED APPLICATIONS

The present application claims priority of Korean Patent Application No. 10-2014-0023196, filed on Feb. 27, 2014, which is incorporated herein by reference in its entirety.

### BACKGROUND

1. Field

Exemplary embodiments of the present invention relate to a ramp signal generator used in a complementary metal oxide semiconductor (CMOS) image sensor (CIS) or the like and, more particularly, to a ramp signal generator including a programmable gain amplifier (GPA) as a voltage buffer.

2. Description of the Related Art

When a CMOS image sensor (CIS) including a single slope analog-digital converter (ADC) uses a current steering digital-analog converter (DAC) for a ramp signal generator, the CIS may control its gain by adjusting the amount of current flowing therein.

With an increase in gain of the OS, the slope of the ramp voltage decreases. This is because the ramp voltage is generated by current flowing through a constant resistor and the current decreases to increase the gain.

Thus, when the CIS has a high gain, very little current may flow and cause serious setting time delays when driving the comparator array. Furthermore, with a reduction in current, the current flowing through each current cell may also decrease and reduce the overdrive voltage of the transistors. In an extreme case, the transistors may operate in a sub-threshold region instead of the saturation region. This may result in the transistors not transmitting an accurate signal current.

### SUMMARY

Various embodiments are directed to a ramp signal generator capable of controlling the magnitude of a voltage using a programmable gain amplifier (PGA) as a voltage buffer.

In an embodiment, a ramp signal generator may include a ramp signal generation unit suitable for generating a ramp signal a gain amplification control unit suitable for outputting a gain amplification control signal for controlling a voltage gain in response to a control signal from a control unit, and a PGA suitable for controlling the voltage gain by amplifying the ramp signal provided from the ramp signal generation unit in response to the gain amplification control signal from the gain amplification control unit.

The gain amplification control unit may include a reset control block suitable for outputting a reset switch control signal to the PGA in response to a reset control signal from the control unit, a variable common mode voltage (VCM) generation unit suitable for generating a variable VCM in response to a VCM level control signal from the control unit, and applying a generated VCM to the PGA, and a gain control block suitable for outputting a capacitor control signal to the PGA in response to a gain control signal from the control unit.

The PGA may include a sampling capacitor having a sampling capacitor value and suitable for sampling the ramp signal provided from the ramp signal generation unit, a feedback capacitor having a feedback capacitor value which is controlled in response to the capacitor control signal from the gain control block, a differential amplifier suitable for amplifying the ramp signal sampled through the sampling capacitor at the ratio of the sampling capacitor value and the feedback capacitor value, and a reset switch suitable for resetting the differential amplifier to the VCM applied from the variable VCM generation unit in response to the reset switch control signal from the reset control block.

In an embodiment, a ramp signal generator may include a ramp signal generation unit suitable for generating a ramp signal through current steering, and a programmable gain amplifier (PGA) suitable for controlling a voltage gain in response to a control signal and amplifying the ramp signal based on a controlled voltage gain.

### BRIEF DESCRIPTION OF THE DRAWINGS

FIG. 1 is a circuit diagram of a voltage mode gain control unit to help understand the present invention.

FIG. 2 is a configuration diagram of a ramp signal generator using a programmable gain amplifier (PGA) in accordance with an embodiment of the present invention.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

Throughout the specification, when an element is referred to as being “coupled” to another element, the element may be “directly coupled” to the other element or “indirectly coupled” to another element, with elements existing therebetween. Similarly if two units or entities are “electrically coupled this may mean they are “directly coupled” or “indirectly coupled”, with further units or entities existing therebetween. Furthermore, when it is stated that when a unit or entity comprises” (or “includes” or “has”) some elements, it should be understood that it may consist of only those elements or it may comprise (or include or have) additional elements as well the listed or stated elements. Additional, in this document, the singular form may include the plural form, and vice versa.

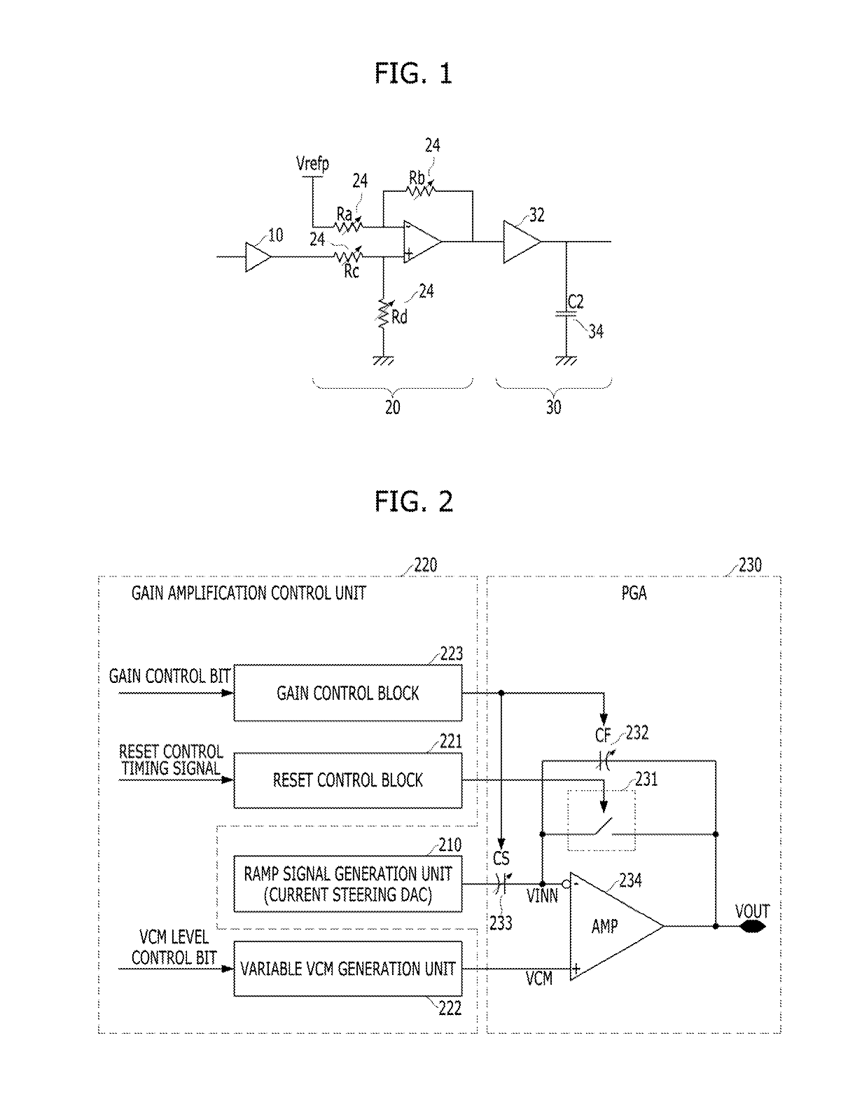

FIG. 1 is a circuit diagram of a voltage mode gain control unit to help understand the present invention.

The voltage mode gain control unit for promoting an understanding of the present invention may control the gain of a ramp signal using a non-inverting voltage amplifier 20.

As illustrated in FIG. 1, the voltage mode gain control unit for promoting an understanding of the present invention may include a buffer amplifier 10, a plurality of resistors 24, and a differential amplifier 22. The buffer amplifier 10 may maintain a constant output voltage (ramp signal) from a capacitive element (not illustrated) at the front stage of the voltage mode gain control unit. Specifically, the buffer amplifier 10 serves to prevent a change in waveform of the ramp signal due to the operation of the voltage mode gain control unit.

A voltage amplification gain Gv is determined depending on the resistance values of the plurality of resistors 24, as expressed by Equation 1.

$$Gv = ( 1 + \frac{Rb}{Ra} ) \times \frac{Rd}{Rc + Rd} \qquad [ Equation 1 ]$$

Thus, as the resistance values Ra, Rb, Rc, and Rd of the resistors 24 are set using variable resistors, the gain of the ramp signal may be controlled.

The voltage mode gain control unit may further include a filtering unit 30 formed at an output terminal thereof, in order to remove various forms of noise.

The filtering unit 30 may include a transconductance amplifier 2 and a compensation capacitive element 34. The transconductance amplifier 32 may be coupled in series to the output terminal of the voltage mode gain control unit, and the compensation capacitive element 34 may have one end coupled to an output terminal of the transconductance amplifier 32. The filtering unit 30 may serve to remove noise included in the ramp signal and then output the ramp signal.

FIG. 2 is a configuration diagram of a ramp signal generator using a programmable gain amplifier (PGA) in accordance with an embodiment of the present invention.

A CMOS image sensor (CIS) using a single-slope ADC changes the slope of a ramp voltage by adjusting a current flowing in a ramp signal generation unit 210, when performing gain control in an analog domain. The ramp signal generation unit 210 may be implemented with a current steering DAC, for example.

The flowing current may differ in the range of a one-time gain to a 16-times gain. The maximum current may where there is a one-time gain.

For example, when the fun swing of the ramp voltage is 800 mV and a resistance of 200Ω is used, the current flow is 4 mA. In this case, the one-time gain is applied.

Since the flowing current becomes 4 mA/16 with the 16-times gain, a very small current may flow to cause serious setting time delays when driving a comparator array. Furthermore, with a decrease in current flow, the current flowing in each current cell may also decrease to reduce the overdrive voltage of the transistors. In an extreme case, a transistor may operate in the sub-threshold region instead of the saturation region. Then, the transistor may not transmit accurate current.

In order to remove the above-described concerns, the flowing current may be set to have a large value. However, the current may be significantly increased in the case of the one-time gain. That is, when the current is set to sufficiently drive a load based on the 16-times gain, the current may be significantly increased in the case of the one-time gain. Then, the magnitude of the resistance may be reduced to less than 200Ω in order to maintain the full swing at 800 mV.

In order to remove these concerns, a voltage buffer for driving the load may be additionally provided. When the voltage buffer is implemented with a programmable gain amplifier (PGA) 230 to control the magnitude of the voltage outputted from the voltage buffer, the ramp signal generation unit 210 may be configured in such a form to reduce current consumption and increase resistance.

Although current consumption is increased by the addition of the voltage buffer, the total current consumption may be significantly reduced because the reduction in current consumption of the ramp signal generation unit 210 is much greater than the increase of the current consumption.

As the PGA 230 performs the gain control function of the ramp signal generation unit 210 at the output terminal of the ramp signal generation unit 210, the current consumed by the ramp signal generation unit 210 may be significantly reduced.

The ramp signal generator using a PGA in accordance with the embodiment of the present invention will be described with reference to FIG. 2.

As illustrated in FIG. 2, the ramp signal generator using a PGA in accordance with the embodiment of the present invention includes a ramp signal generation unit 210, a gain amplification control unit 220, and a PGA 230. The ramp signal generation unit 210 may generate a ramp signal (ramp voltage). The gain amplification control unit 220 may output a gain amplification control signal for controlling a voltage gain in response to a control signal from a control unit (not illustrated). The PGA 230 may control the voltage gain by amplifying the ramp signal provided from the ramp signal generation unit 210 in response to the gain amplification control signal from the gain amplification control unit 220.

The above-described components will now be described in more detail.

First, the ramp signal generation unit 210 generates a ramp voltage (ramp signal) used as a reference voltage and applies the generated ramp voltage to one terminal (negative terminal) of a differential amplifier 234 of the PGA 230, and it may be implemented with a common current steering DAC. Since the PGA 230 performs the gain control function of the current steering DAC at the output terminal of the ramp signal generation unit 210, the current steering DAC used in the embodiment of the present invention does not perform the gain control function.

The gain amplification control unit 220 includes a reset control block 221, a variable common mode voltage (VCM) generation unit 222, and a gain control block 223. The reset control block 221 may output a reset switch control signal to the PGA 230 in response to a reset control signal from the control unit (not illustrated). The variable VCM generation unit 222 may generate a variable common mode voltage in response to a VCM level control signal from the control unit, and apply the generated common mode voltage VCM to the PGA 230. The gain control block 223 may output a capacitor control signal to the PGA 230 in response to a gain control signal from the control unit.

The reset control block 221 then generates the reset switch control signal for turning on or off a reset switch 231 of the PGA 230 in response to the reset control signal from the control unit, and outputs the generated reset switch control signal to the reset switch 231 of the PGA 230. The reset control signal provided from the control unit is a reset control timing signal which is generated once as a pulse before each row of the CIS starts a read-out operation and is received from a control unit within a CIS chip. As an example the control unit may include a digital core block.

The variable VCM generation unit 222 may generate a variable common mode voltage in response to a VCM level control bit from the control unit, and apply the generated common mode voltage VCM to the differential amplifier 234 of the PGA 230. The VCM level control bit may include 0 or 1, and is received from the control unit within the CIS chip. The variable VCM generation unit 222 may increase or decrease the common mode voltage VCM based on the value of the VCM level control bit having a 0 or 1, and apply the generated common mode voltage VCM to the other terminal (positive terminal) of the differential amplifier 234. The generated common mode voltage VCM may linearly increase or decrease based on the value of the VCM level control bit having a 0 or 1. The control unit may include a digital core block, for example.

The gain control block 223 may generate a capacitor control signal for controlling feedback capacitor value and sampling capacitor value or the feedback capacitor value of the PCA in response to the gain control signal from the control unit, and output the generated capacitor control signal to the sampling capacitors 233 and the feedback capacitor 232 of the PGA 230. At this time, the gain control signal provided from the control unit is a gain control bit including a 0 or 1, and may be received from the control unit within the CIS chip. Then, the gain control block 223 may generate the capacitor control signal for increasing or decreasing the feedback and sampling capacitor values or the feedback capacitor value in response to the value of the gain control bit including a 0 or 1, and output the generated capacitor control signal to the feedback and sampling capacitors 232 and 233 or the feedback capacitor 232. Thus, as expressed by Equation 2 below, the voltage amplification gain linearly increases or decreases. The control unit may include a digital core block, for example.

The voltage amplification gain of the PGA 230 is not changed while the PGA 230 is operated, but previously set before the CIS performs an operation for one frame. That is, the digital core block of the CIS may determine the voltage amplification gain based on the brightness of the surrounding environment.

Then, the PGA 230 may control a voltage gain by amplifying the ramp signal provided from the ramp signal generation unit 210 at the ratio of the capacitor value controlled in response to the gain amplification control signal from the gain amplification control unit 220.

The PGA 230 may include a reset switch 231, a feedback capacitor 232, a sampling capacitor 233, and a differential amplifier 234. The reset switch 231 may reset the differential amplifier 234 to the common mode voltage VCM provided from the variable VCM generation unit 222 in response to the reset switch control signal from the reset control block 221. The feedback capacitor 232 may have a feedback capacitor value CF which is controlled in response to the capacitor control signal from the gain control block 223. The sampling capacitor 233 may sample the ramp signal provided from the ramp signal generation unit 210. The differential amplifier 234 may amplify the ramp signal sampled by the sampling capacitor 233 based on the ratio of the value of the sampling capacitor 233 and the value of the feedback capacitor 232 (sampling capacitor value/feedback capacitor value), and output the amplified ramp signal as a signal VOUT.

The reset switch 231 may be formed between one input terminal and an output terminal of the differential amplifier 234. When the reset switch control signal provided from the reset control block 221 is turned to an on-state, the reset switch 231 may be closed. Then, a closed loop feedback network may be formed in the PGA 230, and one input node VINN and an output node VOUT of the differential amplifier 234 may have the same level as the common mode voltage VCM inputted to the other input terminal of the differential amplifier 234 from the variable VCM generation unit 222. This means that the operating (potential) points of the input node and the output node of the differential amplifier 234 are reset to the level of the common mode voltage VCM in order for the differential amplifier 234 to operate at a proper operating point. The variable VCM generation unit 222 is used to apply a variable function in order to prevent a malfunction of the differential amplifier 234, which may occur when the differential amplifier 234 has no proper operating point.

The feedback capacitor 232 may be provided between the input terminal and the output terminal of the differential amplifier 234, and has a value (amount) which is controlled to increase or decrease in response to the capacitor control signal from the gain control block 223. The feedback capacitor 232 may then be implemented with a combination of a plurality of capacitors and switches (not illustrated). Each of the switches may be opened or closed to determine whether to use the corresponding capacitor.

The sampling capacitor 233 may be provided between the output terminal of the ramp signal generation unit 210 and the input terminal of the differential amplifier 234, and may have a value (amount) which is controlled to increase or decrease in response to the capacitor control signal from the gain control block 233. The sampling capacitor 233 may be implemented to have a fixed capacitor value.

The differential amplifier 234 is an inverting differential amplifier which inverts an input of the input terminal (negative terminal). As the reset switch 231 is turned on, the differential amplifier 234 may be reset to the level of the common mode voltage VCM inputted to the other input terminal thereof. Then, when the ramp signal sampled by the sampling capacitor 233 is inputted to the input terminal thereof, the differential amplifier 234 may amplify the ramp signal based on the ratio of the value of the sampling capacitor 233 and the value of the feedback capacitor 232 (sampling capacitor value/feedback capacitor value), and output the amplified ramp signal as a signal VOUT.

Thus, the voltage amplification gain Gv may be determined based on the ratio of the sampling capacitor value CS and the feedback capacitor value CF, as expressed by Equation 2 below.

Gv=CS(sampling capacitor value)/CF(feedback capacitor value) [Equation 2]

As described above, when the ramp signal is inputted through the sampling capacitor 233 from the ramp signal generation unit 210, the PGA 230 may amplify the ramp signal based on the ratio of the sampling capacitor value CS and the feedback capacitor value CF, which is controlled in response to the gain amplification control signal from the gain amplification control unit 220.

The ramp signal generator in accordance with the embodiment of the present invention may control the slope of the ramp signal (ramp voltage) generated from the ramp signal generation unit 210 (current steering DAC) using the capacitor-based PGA 230 thereby controlling the entire gain of the CIS.

The ramp signal generator in accordance with the embodiment of the present invention may be applied to various structures using a single-slope ADC.

Now, the PGA 230 in accordance with the embodiment of the present invention and the voltage mode gain control unit 20 of FIG. 1 will be comparatively described.

In the voltage mode gain control unit 20 of FIG. 1, the passive element used in the feedback network is implemented with a resistor. On the other hand, in the embodiment of the present invention, the capacitor may be used to prevent current consumption in the feedback network.

Furthermore, the voltage mode gain control unit 20 of FIG. 1 receives the ramp voltage through the resistor. In this case, when the current steering DAC is used, an accurate voltage may not be obtained because the resistor for generating the voltage of the current steering DAC and the resistor in the feedback network of the voltage mode gain control unit 20 are coupled in parallel to each other. Thus, in the voltage mode gain control unit 20 of FIG. 1, the buffer 10 may be inserted between the part for generating the ramp voltage and the voltage mode gain control unit 20 to isolate the two circuits from each other. In this case, an additional current for the buffer 10 is generated. In the embodiment of the preset invention, however, since the capacitor is used in the feedback network, the above-described situation does not occur.

Furthermore, a capacitor has more accurate matching characteristics than a resistor. Thus, the PGA using a capacitor in accordance with the embodiment of the present invention may perform gain control more precisely than the voltage mode gain controller 20 of FIG. 1, which controls the gain using the resistor.

Furthermore, in the voltage mode gain control unit 20 of FIG. 1, the starting level of the ramp voltage is determined depending on the current flowing in the feedback network. However, in accordance with the embodiment of the present invention, the starting level of the ramp voltage may be controlled by changing the common mode voltage inputted to the PGA.

In accordance with the embodiment of the present invention, the voltage buffer may be implemented with the PGA so as to control the magnitude of the voltage.

Furthermore, the amount of current flowing in the ramp signal generation unit may be reduced.

Furthermore, although current consumption is increased by the addition of the voltage buffer, the total current consumption may be significantly reduced because the reduction in current consumption of the ramp signal generation unit is much larger than the corresponding increase in current consumption.

Although various embodiments have been described for illustrative purposes, it will be apparent to those skilled in the art that various changes and modifications may be made without departing from the spirit and scope of the invention as defined in the following claims.

What is claimed is:

1. A ramp signal generator comprising:
a ramp signal generation unit suitable for generating a ramp signal;
a gain amplification control unit suitable for outputting a gain amplification control signal for controlling a voltage gain in response to a control signal from a control unit; and
a programmable gain amplifier (PGA) suitable for controlling the voltage gain by amplifying the ramp signal provided from the ramp signal generation unit in response to the gain amplification control signal from the gain amplification control unit.

2. The ramp signal generator of claim 1, wherein the gain amplification control unit comprises:
a reset control block suitable for outputting a reset switch control signal to the PGA in response to a reset control signal from the control unit;
a variable common mode voltage (VCM) generation unit suitable for generating a variable VCM in response to a VCM level control signal from the control unit, and applying a generated VCM to the PGA; and
a gain control block suitable for outputting a capacitor control signal to the PGA in response to a gain control signal from the control unit.

3. The ramp signal generator of claim 2, wherein the gain control block generates the capacitor control signal for controlling feedback and sampling capacitor values or the feedback capacitor value of the PGA in response to the gain control signal from the control unit, and outputting the capacitor control signal to the PGA.

4. The ramp signal generator of claim 1, wherein the PGA controls the voltage gain by amplifying the ramp signal provided from the ramp signal generation unit at a ratio of a capacitor value controlled in response to the gain amplification control signal from the gain amplification control unit.

5. The ramp signal generator of claim 2, wherein the PGA comprises:
a sampling capacitor having a sampling capacitor value and suitable for sampling the ramp signal provided from the ramp signal generation unit;
a feedback capacitor having a feedback capacitor value which is controlled in response to the capacitor control signal from the gain control block;
a differential amplifier suitable for amplifying the ramp signal sampled through the sampling capacitor at the ratio of the sampling capacitor value and the feedback capacitor value; and
a reset switch suitable for resetting the differential amplifier to the VCM applied from the variable VCM generation unit in response to the reset switch control signal from the reset control block.

6. The ramp signal generator of claim 5, wherein the sampling capacitor value is controlled in response to the capacitor control signal from the gain control block.

7. The ramp signal generator of claim 5, wherein the differential amplifier receives the ramp signal sampled by the sampling capacitor through one input terminal thereof and the VCM applied from the variable VCM generation unit through the other input terminal thereof, amplifies the ramp signal based on the ratio of the sampling capacitor value and the feedback capacitor value (the sampling capacitor value/the feedback capacitor value), and outputs an amplified ramp signal.

8. The ramp signal generator of claim 1, wherein the ramp signal generation unit comprises a current steering digital-analog converter (DAC).

9. A ramp signal generator comprising:
a ramp signal generation unit suitable for generating a ramp signal through current steering; and
a programmable gain amplifier (PGA) suitable for controlling a voltage gain in response to a control signal and amplifying the ramp signal based on a controlled voltage gain.

10. The ramp signal generator of claim 9, further comprising:
a gain amplification control unit suitable for generating a reset switch control signal, a variable common mode voltage, and a capacitor control signal as the control signal, and outputting the control signal to the PGA.

11. The ramp signal generator of claim 10, wherein the PGA is reset to the variable common mode voltage in response to the reset switch control signal and amplifies the ramp signal at a ratio of a capacitor value controlled in response to the capacitor control signal.
